(19) United States
(12) Patent Application Publication
(10) Pub. No.: US 2025/0075310 A1
(43) Pub. Date: Mar. 6, 2025

(54) METHOD FOR MANUFACTURING ELECTRET MATERIAL

(71) Applicant: TOYOTA JIDOSHA KABUSHIKI KAISHA, Toyota-shi (JP)

(72) Inventors: Kenichi OKUMURA, Gotemba-shi (JP); Shinichi URABE, Shizuoka-ken (JP)

(73) Assignee: TOYOTA JIDOSHA KABUSHIKI KAISHA, Toyota-shi (JP)

(21) Appl. No.: 18/743,119

(22) Filed: Jun. 14, 2024

(30) Foreign Application Priority Data
Sep. 6, 2023 (JP) 2023-144377

(51) Int. Cl. C23C 14/48; C23C 14/58; C23C 16/56; C23C 28/04; H01G 7/02

(52) U.S. Cl. CPC C23C 14/48; C23C 14/5806; C23C 16/56; C23C 28/04; H01G 7/02

(57) ABSTRACT

A method for manufacturing an electret material includes: an ion implantation step of implanting ions into an insulator; a heat treatment step of, after the ion implantation step, performing a heat treatment on the insulator by supplying energy from the outside; and a charging step of charging the ions in the insulator after the heat treatment step.

### CROSS-REFERENCE TO RELATED APPLICATION

This application claims priority to Japanese Patent Application No. 2023-144377 filed on Sep. 6, 2023, incorporated herein by reference in its entirety.

### BACKGROUND

### 1. Technical Field

The present disclosure relates to methods for manufacturing an electret material.

### 2. Description of Related Art

Electret materials, which are the electrical equivalent of permanent magnets that permanently retain their magnetism, are materials that permanently retain their charge. The electret materials are primarily used in microphones, motors, etc. The electret materials include those composed of an organic material and those composed of an inorganic material. In some electret materials, some kind of treatment is performed on the materials to induce polarization so that they retain their charge, whereas in other electret materials, charge is trapped in the materials themselves. Various techniques have been proposed for a method for manufacturing an electret material, as disclosed in Japanese Unexamined Patent Application Publication No. 2008-021786 (JP 2008-021786 A). Such related art techniques include a technique using ion implantation.

### SUMMARY

In the related art, charge of ions is used as it is to charge an electret material. Therefore, the charge tends to leak through, for example, defects caused by the ion implantation. One possible way to reduce the defects is to perform a heat treatment. However, performing a heat treatment is not effective enough because the charge already on the ions leaks due to the heat treatment.

The present disclosure was made in view of the above circumstances, and it is a primary object of the present disclosure to provide a method for manufacturing an electret material that can reduce leakage of charge.

The present disclosure includes the following aspect.

A method for manufacturing an electret material according to an aspect of the present disclosure includes: an ion implantation step of implanting ions into an insulator; a heat treatment step of, after the ion implantation step, performing a heat treatment on the insulator by supplying energy from outside; and a charging step of charging the ions in the insulator after the heat treatment step.

In the method according to the above method, in the ion implantation step, the ions may be implanted into the insulator to a depth away from a surface of the insulator.

The method according to the above aspect may further include a film formation step of, after the ion implantation step or the heat treatment step, forming an insulating protective film on a surface on an ion-implanted side of the insulator.

In the method according to the above aspect, when electrons are trapped by the ions, an energy level of a valence band of the insulating protective film may be higher than an energy level of a valence band of the insulator.

In this case, an energy level of a conduction band of the insulating protective film is preferably higher than an energy level of a conduction band of the insulator.

In the method according to the above aspect, when holes are trapped by the ions, the energy level of the conduction band of the insulating protective film may be lower than the energy level of the conduction band of the insulator.

In this case, the energy level of the valence band of the insulating protective film is preferably lower than the energy level of the valence band of the insulator.

The present disclosure can provide an electret material that can reduce leakage of charge.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a flowchart illustrating an example of a method for manufacturing an electret material of the present disclosure;

FIG. 2 is a schematic cross-sectional view showing an example of an electret material obtained by the manufacturing method of the present disclosure;

FIG. 3A is a schematic diagram showing an example of the case where the ion implanted into the insulator traps the electron, and the case where the insulating protective film is a single-layer film, and the energy level of the valence band of the insulating protective film higher than the energy level of the valence band of the insulator (SiO₂ in FIG. 3A);

FIG. 3B is a schematic diagram showing an example of the case where the ion implanted into the insulator traps the electron, the case where the insulating protective film is a single-layer film, and the case where the energy level of the valence band of the insulating protective film higher than the energy level of the valence band of the insulator (SiO₂ in FIG. 3B) and the energy level of the conduction band of the insulating protective film is higher than the energy level of the conduction band of the insulator;

FIG. 4A is a schematic diagram showing an example of the substrate Si/insulator SiO₂/first insulating protective film HfO₂/second insulating protective film Si₃N₄ when ions implanted in the insulator are trapping electrons, when the insulating protective film is a two-layer film, when the energy level of the valence band of the first insulating protective film on the insulator side is higher than the energy level of the valence band of the insulator, and when the energy level of the valence band of the second insulating protective film on the outermost surface side is higher than the energy level of the valence band of the first insulating protective film;

FIG. 4B is a schematic diagram showing an example of the substrate Si/insulator SiO₂/first insulating protective film ZrO₂/second insulating protective film Si₃N₄ when ions implanted in the insulator are trapping electrons, when the insulating protective film is a two-layer film, when the energy level of the valence band of the first insulating protective film on the insulator side is higher than the energy level of the valence band of the insulator, and when the energy level of the valence band of the second insulating protective film on the outermost surface side is higher than the energy level of the valence band of the first insulating protective film;

FIG. 4C is a schematic diagram showing an example of substrate Si/insulator SiO₂/first insulating protective film Y₂O₃/second insulating protective film Si₃N₄ when ions implanted into the insulator trap electrons, when the insulating protective film is a two-layer film, when the energy level of the valence band of the first insulating protective film on the insulator side is higher than the energy level of the valence band of the insulator, when the energy level of the valence band of the second insulating protective film on the outermost surface side is higher than the energy level of the valence band of the first insulating protective film;

FIG. 4D is a schematic diagram showing an example of substrate Si/insulator SiO₂/first insulating protective film AlₓGa₁₋ₓO₃/second insulating protective film Si₃N₄ when the ions implanted into the insulator trap electrons, when the insulating protective film is a two-layer film, when the energy level of the valence band of the first insulating protective film on the insulator side is higher than the energy level of the valence band of the insulator, and when the energy level of the valence band of the second insulating protective film on the outermost surface side is higher than the energy level of the valence band of the first insulating protective film;

FIG. 5A is a schematic diagram showing an example of a case where ions implanted into an insulator trap holes, and a case where the insulating protective film is a single-layer film, and a case where the energy level of the conduction band of the insulating protective film is lower than the energy level of the conduction band of the insulator (SiO₂ in FIG. 5A);

FIG. 5B is a schematic diagram showing an example of the case where ions implanted into an insulator trap holes, when the insulating protective film is a single-layer film, and when the energy level of the valence band of the insulating protective film is lower than the energy level of the valence band of the insulator (SiO₂ in FIG. 5B), and the energy level of the conduction band of the insulating protective film is lower than the energy level of the conduction band of the insulator;

FIG. 6A is a schematic diagram showing an example of substrate Si/insulator SiO₂/first insulating protective film Si₃N₄/second insulating protective film Y₂O₃, when the ions implanted into the insulator trap holes, when the insulating protective film is a two-layer film, and when the conduction band of the first insulating protective film on the insulator side is at an energy level lower than the conduction band of the insulator, the conduction band of the second insulating protective film on the outermost surface side is lower than the conduction band of the first insulating protective film;

FIG. 6B is a schematic diagram showing an example of substrate Si/insulator SiO₂/first insulating protective film Y₂O₃/second insulating protective film HfO₂ when ions implanted into the insulator trapped holes, when the insulating protective film is a two-layer film, and when the energy level of the conduction band of the first insulating protective film on the insulator side is lower than the energy level of the conduction band of the insulator, and the energy level of the conduction band of the second insulating protective film on the outermost surface is lower than the energy level of the conduction band of the first insulating protective film; and

FIG. 6C is a schematic diagram showing an example of substrate Si/insulator Si₃N₄/first insulating protective film Y₂O₃/second insulating protective film HfO₂ when the ions implanted into the insulator trap holes, when the insulating protective film is a two-layer film, and when the energy level of the conduction band of the first insulating protective film on the insulator side is lower than the energy level of the conduction band of the insulator, the energy level of the conduction band of the second insulating protective film on the outermost surface side is lower than the energy level of the conduction band of the first insulating protective film.

### DETAILED DESCRIPTION OF EMBODIMENTS

Hereinafter, embodiments according to the present disclosure will be described. It should be noted that matters other than those specifically mentioned in the present specification and necessary for the implementation of the present disclosure (for example, a general configuration and a manufacturing process of an electret material which does not characterize the present disclosure) can be understood as design matters of a person skilled in the art based on the prior art in the field. The present disclosure can be implemented based on the contents disclosed in the present specification and the technical common knowledge in the field. In addition, dimensional relationships (length, width, thickness, and the like) in the drawings do not reflect actual dimensional relationships.

The present disclosure provides a method for manufacturing an electret material. The method includes: an ion implantation step of implanting ions into an insulator; a heat treatment step of, after the ion implantation step, performing a heat treatment on the insulator by supplying energy from outside; and a charging step of charging the ions in the insulator after the heat treatment step.

Insulators such as SiO₂ used in the prior art have so-called defect levels (defects at various energy positions in the forbidden band). Therefore, the defect level becomes a path root of the charge in the insulator, the electret material formed by trapping the charge by implanting ions into the insulator, the holding performance of the charge is inferior. In particular, under a high electric field such as driving a motor, it becomes difficult to retain the charge. The present disclosure relates to an electret material of a type that traps charge, and the charge is susceptible to external influences, and charge is removed (leaked) by contact with an object, ambient moisture, or the like. In the present disclosure, in order to prevent leakage of charge from an electret material, ions are implanted into a material to be an electret material, and thereafter, the defect level in the material is reduced, so that the insulating property is ensured on the surface of the material so that the charge does not leak.

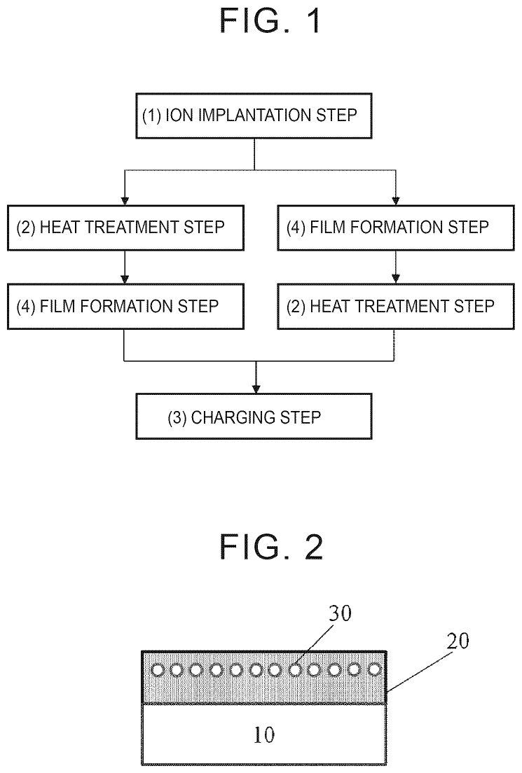

FIG. 1 is a flowchart illustrating an example of a method for manufacturing an electret material according to the present disclosure. As shown in FIG. 1, a method for manufacturing an electret material of the present disclosure includes (1) ion implantation step, (2) heat treatment step, and (3) charging step, and as necessary, further includes (4) film formation step after (1) ion implantation step or (2) heat treatment step. FIG. 2 is a schematic cross-sectional view showing an example of an electret material obtained by the manufacturing method of the present disclosure. The electret material includes a substrate 10 and an insulator 20 disposed on the substrate 10, and the charge 30 is charged in the insulator 20.

### (1) Ion Implantation Step

The ion implantation step is a step of implanting ions into the insulator. In the ion implantation step, the ions are preferably implanted into the insulator to a depth away from the surface of the insulator. In order to reduce leakage of charge trapped in the insulator, ions are implanted into the insulator to a depth away from the surface of the insulator, and the distance from the ions to the insulator surface is sufficiently kept away to ensure the insulating properties. Charge has a phenomenon called tunneling effect, in particular, electrons pass through the insulator stochastically even if the insulator is thick. Therefore, it is preferable that the ion be separated from the insulator surface, and the ion implantation depth is preferably 100 nm from 60 nm in depth from the surface of the insulator. The insulator is SiO₂, Si₃N₄, HfO₂, ZrO₂, Y₂O₃, Al₂O₃, AlₓGa₁₋ₓO₃, InₓGa₁₋ₓAs, GaSb, MoS₂, diamond, etc. Ions implanted into the insulator include ions of elements such as Al, Ar, As, Au, B, Cl, F, K, N, Ne, and P. The implantation dose may be 1×10¹¹/cm² or more.

The insulator may be disposed on the substrate. The insulator may be disposed on one side of the substrate, on both sides of the substrate, or on the entire surface of the substrate. The substrate may be Si, Al₂O₃, diamond, etc.

The thickness of the base plate is preferably equal to or greater than 500 nm. The thickness of the insulator is preferably equal to or greater than 200 nm. Prior to disposing the insulator on the substrate, the substrate may be subjected to a HF cleaning process, an H₂SO₄/H₂O₂ cleaning process, or the like. The method of disposing the insulator on the substrate includes, for example, a method of oxidizing Si substrate by being heated in a dry atmosphere when SiO₂ is used. The heating temperature is preferably, for example, 1100° C. or higher. As a method of disposing the insulator on the substrate, a method similar to the method exemplified in (4) film formation step described later in addition to the above can also be employed.

### (2) Heat Treatment Step

The heat treatment step is a step of, after the ion implantation step, performing a heat treatment on the insulator by supplying energy from outside. In general, defects (broken bonds between atoms) are activated by the application of energy, such as heat, from outside the material and recombine with nearby atoms. After ions are implanted into the insulator, energy is supplied from outside the insulator to perform a heat treatment on the insulator. This can reduce defects generated in the insulator. The heat treatment may be performed in a nitrogen-based gas (N₂ annealing). H₂ gas may be added to noble gas during the heat treatment (also referred to as hydrogen sintering etc.) Hydrogen sintering promotes the effect that the added H and atoms combine to annihilate the defect, apart from recombining the bonds between the broken atoms. The heat treatment temperature varies depending on the material, but is preferably 200° C. or more and 600° C. or less. The heat treatment time is preferably performed for five minutes or more.

### (3) Charging Step

The charging step is a step of charging the ions in the insulator after the heat treatment step. Some of charge of the implanted ions leaks as a result of the heat treatment. However, since the ions implanted into the insulator serve as charge traps, leakage of charge of the electret material can be reduced by performing a charging process of transferring charge from the outside of the insulator to the charge trap. As the charging treatment, corona discharge, electron beam (electron beam irradiation), photoionization (soft X-ray), or the like can be used.

### (4) Film Formation Step

The film formation step is a step of, after the ion implantation step or the heat treatment step, forming an insulating protective film on a surface on an ion-implanted side of the insulator. In order to reduce leakage of charge trapped in the insulator, an insulating protective film may be bonded to the ion-implanted insulator. For example, the insulator can be formed by a Sol-Gel method, Chemical Vapor Deposition (CVD), or Atomic Layer Deposition (ALD). Among these, CVD or ALD that forms an insulator with an good film quality may be used. The insulating protective film is made of, for example, SiO₂, Si₃N₄, HfO₂, ZrO₂, Y₂O₃, Al₂O₃, AlₓGa₁₋ₓO₃, InₓGa₁₋ₓAs, GaSb, or MoS₂. The insulating protective film and the insulator may be made of the same material or different materials. The insulating protective film need only be formed on the surface on the ion-implanted side of the insulator. The insulating protective film may be formed on both surfaces of the insulator when ions are implanted on both surfaces of the insulator, or may be formed on the entire surface of the insulator when ions are implanted on the entire surface of the insulator. The insulating protective film may be a single-layer film made of one kind of material layer, or may be a multi-layer film consisting of two or more layers of different kinds of materials. The thickness of the insulating protective film is preferably equal to or greater than 100 nm.

When electrons are trapped in the ions, a material in which the energy level of the valence band of the insulating protective film is higher than the energy level of the valence band of the insulator is used. In this case, the energy level of the conduction band of the insulating protective film is preferably higher than the energy level of the conduction band of the insulator. Examples of a method for controlling whether electrons are trapped in ions or holes are trapped in ions include a method using corona discharge as a charging process in the charging step (3).

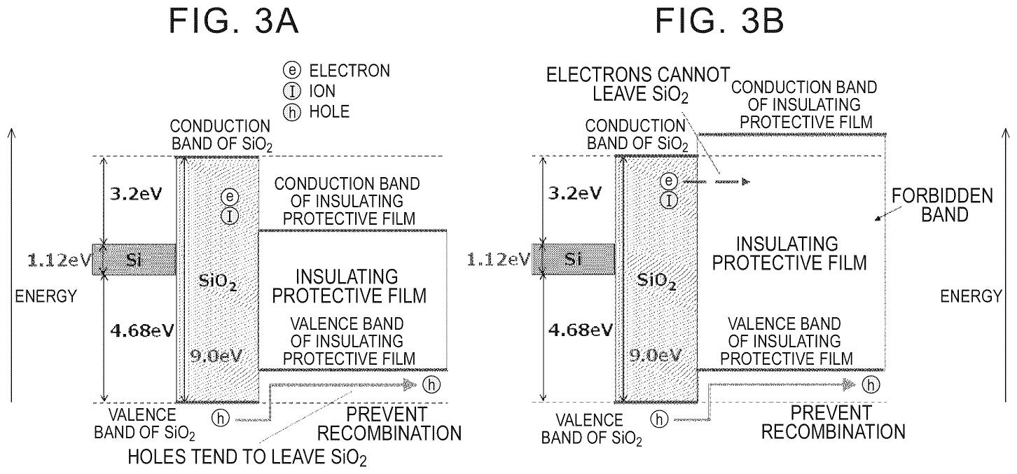

FIG. 3A is a schematic diagram illustrating an example of a case where ions implanted into an insulator trap electrons, a case where an insulating protective film is a single-layer film, and a case where the energy level of the valence band of the insulating protective film is higher than the energy level of the valence band of the insulator (SiO₂ in FIG. 3A). FIG. 3B is a schematic diagram showing an example of a case where ions implanted into an insulator trap electrons, the case where the insulating protective film is a single-layer film, the energy level of the valence band of the insulating protective film is higher than the energy level of the valence band of the insulator (SiO₂ in FIG. 3B), and the energy level of the conduction band of the insulating protective film is higher than the energy level of the conduction band of the insulator. Si shown in FIGS. 3A and 3B are substrates. In the insulator, electrons trapped in the implanted ions are present, and at the same time, holes may be present in the insulator. At this time, since the electrons and the holes are present in the same insulator, the physical distance is close, and there is a possibility that the electrons and the holes recombine. In order to prevent this, if the valence band of the insulating protective film is higher than that of the insulator as shown in FIG. 3A, it is intended to be directed in an energetically stable direction (upward direction in FIG. 3A) for holes. Therefore, the holes move into the insulating protective film while diffusing (moving) through the insulator. Energy such as heat is released when holes move from the insulator to the insulating protective film, that is, when the holes move to the insulating protective film which is more energy-stable. Therefore, in order for the holes once transferred to the insulating protective film to move to the insulator, it is necessary to supply energy from the outside, so that the hole is less likely to return to the insulator as the level difference in the valence band increases. In FIG. 3A, electrons trapped by the insulator tend to move toward a lower-energy direction (downward in the drawing) opposite to the hole, and therefore, movement to the insulating protective film as well as the hole may occur stochastically (quantum-mechanical). On the other hand, when the conduction band of the insulating protective film is higher than the conduction band of the insulator as in FIG. 3B, electrons cannot move to the forbidden band of the insulating protective film (energy level where electrons are not allowed to stay). Therefore, the electrons tend to remain in the insulator without moving to the insulating protective film. Therefore, recombination of electrons and holes is less likely to occur. In description regarding FIGS. 3A and 3B, it is assumed that the insulator to which ions are implanted is sufficiently thick because holes and electrons may move also to Si that is a substrate. If the implanted ions are present inside the insulator at a depth away from the surface and are sufficiently far from Si of the substrate when viewed from the ions, the likelihood of electrons moving to the substrate will be negligibly small if the insulating properties of the insulator are good. One hole may migrate to Si of the substrate. This is advantageous because it can be expected to prevent recombination of electrons. Note that since the holes do not have charge, even if they recombine with electrons, the electret material does not lose charge. However, the electret material may come into contact with H₂O, ions, contaminants, and the like present in the atmosphere. Those present in the atmosphere, since the transfer of charge when in contact with the electret material may be performed, if the electrons implanted into the insulator cannot be immobilized in the insulator, the electrons recombined with the holes can move in the insulator and the insulating protective film. The electrons move to H₂O or the like adsorbed on the surface of the electret material. When H₂O or the like, which has received this electron, moves away from the electret material, charge is removed from the electret material as a result. The materials that satisfy the condition shown in FIG. 3A include a combination of SiO₂ as an insulator and Si₃N₄, HfO₂, ZrO₂, Y₂O₃, Al₂O₃, or AlₓGa₁₋ₓO₃ as an insulating protective film. Examples of the material that satisfies the condition shown in FIG. 3B include a combination of SiO₂ as an insulator and InₓGa₁₋ₓAs, GaSb, or MoS₂ as an insulating protective film.

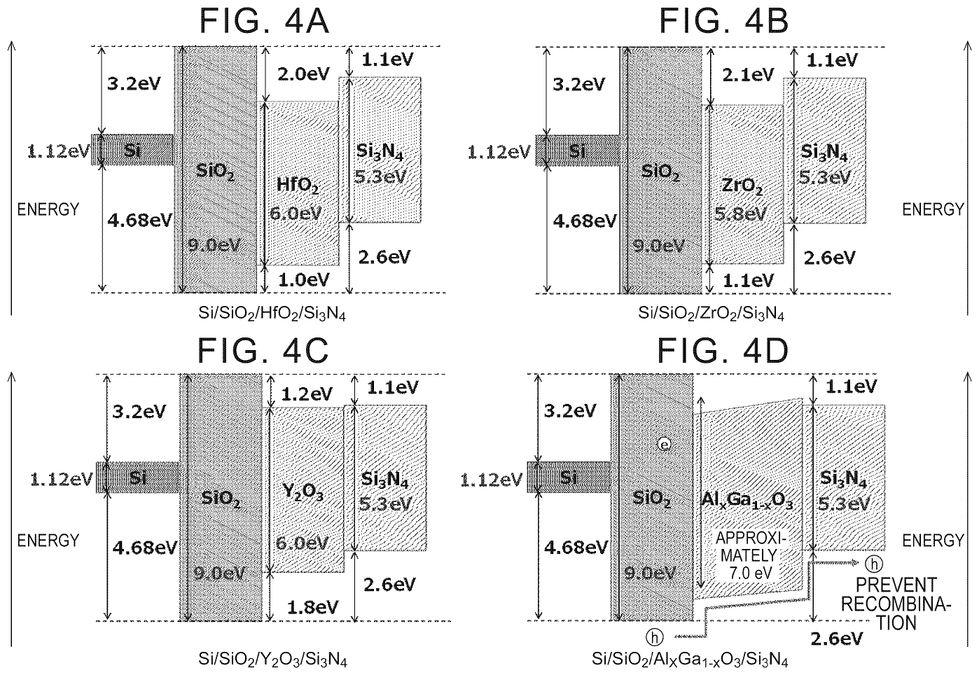

FIGS. 4A to 4D illustrate a case where the ions implanted into the insulator trap electrons, a case where the insulating protective film is a two-layer film, a case where the energy level of the valence band of the first insulating protective film on the insulator side is higher than the energy level of the valence band of the insulator, and a case where the energy level of the valence band of the second insulating protective film on the outermost surface side is higher than the energy level of the valence band of the first insulating protective film. FIG. 4A is a schematic view illustrating an example of substrate Si/insulator SiO₂/first insulating protective film HfO₂/second insulating protective film Si₃N₄. FIG. 4B is a schematic view illustrating an example of substrate Si/insulator SiO₂/first insulating protective film ZrO₂/second insulating protective film Si₃N₄. FIG. 4C is a schematic view showing an example of substrate Si/insulator SiO₂/first insulating protective film Y₂O₃/second insulating protective film Si₃N₄. FIG. 4D is a schematic view showing an example of substrate Si/insulator SiO₂/first insulating protective film AlₓGa₁₋ₓO₃/second insulating protective film Si₃N₄. In the case where ions implanted into the insulator trap electrons and the case where the insulating protective film is a two-layer film, basically the same idea as in the case where the previous insulating protective film is made of a single layer can be adopted. The insulating protective film is a two-layer film. Therefore, as holes move from the insulator to the first insulating protective film on the insulator side for an energetically stable place and further diffuse from the first insulating protective film to the second insulating protective film on the outermost surface side, holes are physically separated from the ion-implanted insulator, so that recombination with electrons is less likely to occur. FIG. 4D shows the case where a gradual change in the composition ratio (x) results in an oblique forbidden band (graded band gap). In FIGS. 4A to 4D, Si₃N₄ is used as the second insulating protective film which is the outermost layer. The second insulating protective film that is the outermost layer may be Si₃N₄ because Si₃N₄ is less likely to allow moisture to pass therethrough due to its low moisture permeability and is less likely to cause a phenomenon in which moisture reaches the insulator and remove the charge.

In the case where holes are trapped in the ions, a material in which the energy level of the conduction band of the insulating protective film is lower than the energy level of the conduction band of the insulator is used. In this case, the energy level of the valence band of the insulating protective film is preferably lower than the energy level of the valence band of the insulator.

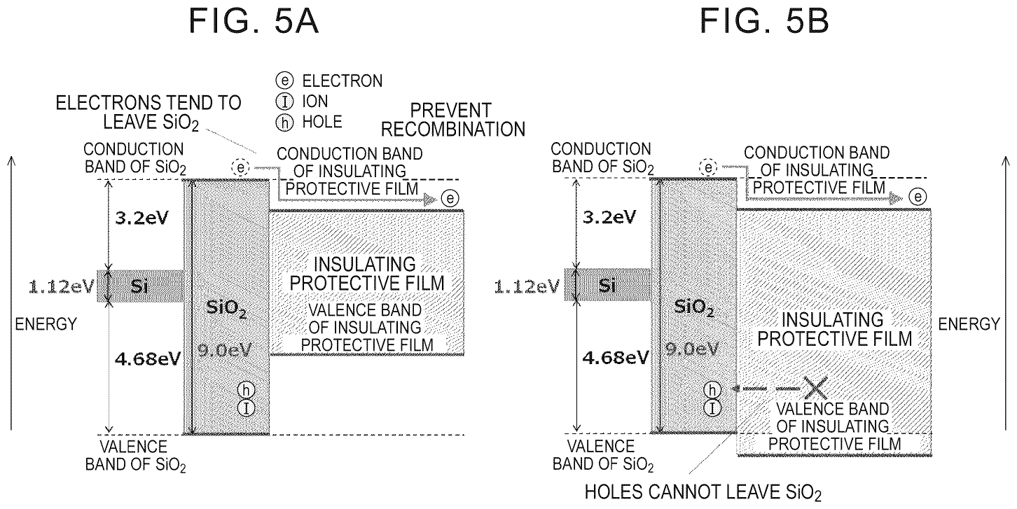

FIG. 5A is a schematic diagram showing an example of a case where ions implanted into an insulator trap holes, and a case where an insulating protective film is a single-layer film, and a case where the energy level of the conduction band of the insulating protective film is lower than the energy level of the conduction band of the insulator (SiO₂ in FIG. 5A). FIG. 5B is a schematic diagram showing an example of the case where ions implanted into an insulator trap holes, and the case where the insulating protective film is a single-layer film, and the energy level of the valence band of the insulating protective film is lower than the energy level of the valence band of the insulator (SiO₂ in FIG. 5B), and the energy level of the conduction band of the insulating protective film is lower than the energy level of the conduction band of the insulator. Si shown in FIGS. 5A and 5B are substrates. In FIGS. 3A, 3B, 4A, 4B, 4C, and 4D described above, the case where electrons are trapped in ions is mentioned, but as shown in FIGS. 5A and 5B, the case where holes are trapped in ions rather than electrons may be possible. The difference between an electron and a hole trapped by an ion is that the energy level of the holes trapped by the ions is close to the valence band.

It should be noted that when ions trap electrons, the ions are considered to be located at an energy level close to the conduction band of SiO₂. If an electron is trapped near the valence band, the probability that the electron will recombine with SiO₂ is high, so it is considered that the probability that the electron can exist is low. Since the opposite concept can be applied when holes are trapped in the ions, the energy level of the holes trapped by the ions is considered to be close to the valence band. Thus, when the trapped is a hole, the positions of the conduction band and valence band are reversed relative to when the trapped is an electron. In FIG. 5A, since the energy level of the conduction band of the insulating protective film is lower than the energy level of the conduction band of the insulator, electrons move from the insulator to the insulating protective film, so that recombination of electrons and holes can be reduced. In FIG. 5A, since the energy level of the valence band of the insulating protective film is higher than the energy level of the valence band of the insulator, the electrons and the holes may recombine with each other due to the movement of the holes of the insulator to the insulating protective film. On the other hand, in FIG. 5B, the energy level of the valence band of the insulating protective film is lower than the energy level of the valence band of the insulator, and the energy level of the conduction band of the insulating protective film is lower than the energy level of the conduction band of the insulator. Therefore, even if electrons move from the insulator to the insulating protective film, holes of the insulator tend to remain in the insulator without moving to the insulating protective film, and the recombination of electrons and holes can be more desirably reduced. The materials that satisfy the condition shown in FIG. 5A include a combination of SiO₂ as an insulator and Si₃N₄, HfO₂, ZrO₂, Y₂O₃, Al₂O₃, or AlₓGa₁₋ₓO₃ as an insulating protective film.

The materials that satisfy the condition shown in FIG. 5B include a combination of Si₃N₄ as an insulator and HfO₂, ZrO₂, or Y₂O₃ as an insulating protective film.

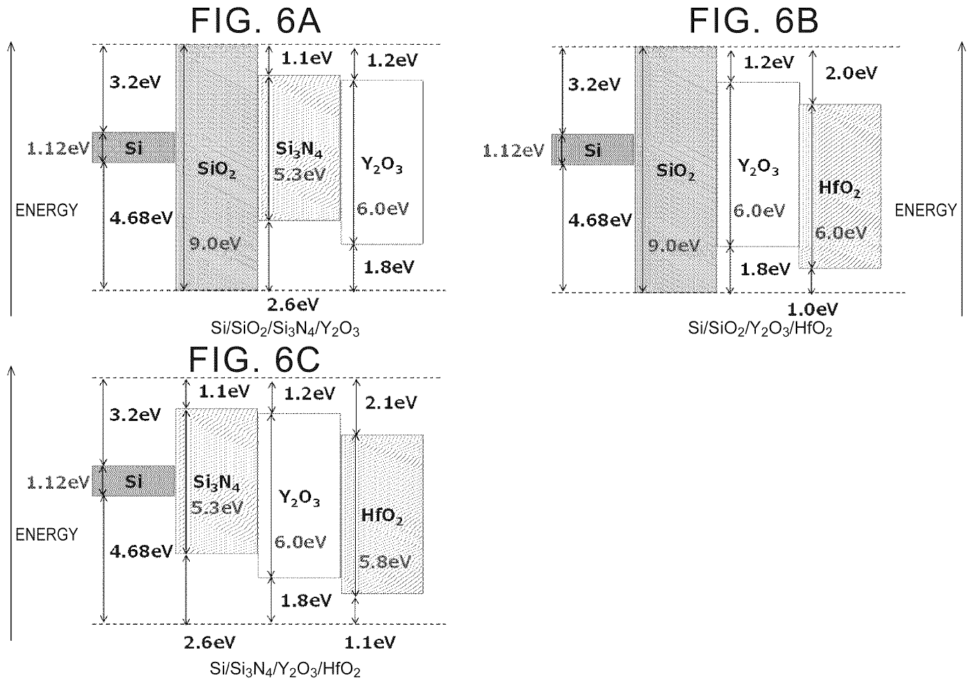

FIGS. 6A to 6C show a case where the ions implanted into the insulator trap holes, a case where the insulating protective film is a two-layer film, a case where the energy level of the conduction band of the first insulating protective film on the insulator side is lower than the energy level of the conduction band of the insulator, and a case where the energy level of the conduction band of the second insulating protective film on the outermost surface side is lower than the energy level of the conduction band of the first insulating protective film. FIG. 6A is a schematic diagram showing an example of substrate Si/insulator SiO₂/first insulating protective film Si₃N₄/second insulating protective film Y₂O₃. FIG. 6B is a schematic diagram showing an example of substrate Si/insulator SiO₂/first insulating protective film Y₂O₃/second insulating protective film HfO₂. FIG. 6C is a schematic diagram showing an example of substrate Si/insulator Si₃N₄/first insulating protective film Y₂O₃/second insulating protective film HfO₂. In the case where the ions implanted into the insulator trap holes, and in the case where the insulating protective film is a two-layer film, basically the same idea as in the case where the previous insulating protective film is a single-layer film can be adopted. Since the insulating protective film is a two-layer film, as electrons move from the insulator to the first insulating protective film on the insulator side and further diffuse from the first insulating protective film to the second insulating protective film on the outermost surface side, the electrons are physically separated from the ion-implanted insulator, so that recombination with holes is less likely to occur. The energy level of the valence band of the second insulating protective film is lower than the energy level of the valence band of the first insulating protective film. Therefore, even if the holes of the insulator move from the insulator to the first insulating protective film, it is difficult to move from the first insulating protective film to the second insulating protective film, so that the recombination of electrons and holes can be more desirably reduced.

What is claimed is:

1. A method for manufacturing an electret material, the method comprising:
an ion implantation step of implanting ions into an insulator;
a heat treatment step of, after the ion implantation step, performing a heat treatment on the insulator by supplying energy from outside; and
a charging step of charging the ions in the insulator after the heat treatment step.

2. The method according to claim 1, wherein in the ion implantation step, the ions are implanted into the insulator to a depth away from a surface of the insulator.

3. The method according to claim 1, further comprising a film formation step of, after the ion implantation step or the heat treatment step, forming an insulating protective film on a surface on an ion-implanted side of the insulator.

4. The method according to claim 3, wherein when electrons are trapped by the ions, an energy level of a valence band of the insulating protective film is higher than an energy level of a valence band of the insulator.

5. The method according to claim 3, wherein when holes are trapped by the ions, an energy level of a conduction band of the insulating protective film is lower than an energy level of a conduction band of the insulator.
